(19) United States
(12) Patent Application Publication
(10) Pub. No.: US 2018/0284851 A1
(43) Pub. Date: Oct. 4, 2018

(54) FILLER INTERFACE HEAT TRANSFER SYSTEM AND DEVICES AND METHODS FOR SAME

(71) Applicants: Georg Seidemann, Landshut (DE); Bernd Waidhas, Pettendorf (DE); Thomas Wagner, Regelsbach (DE); Andreas Wolter, Regensburg (DE); Sonja Koller, Regensburg (DE); Vishnu Prasad, Putzbrunn (DE)

(72) Inventors: Georg Seidemann, Landshut (DE); Bernd Waidhas, Pettendorf (DE); Thomas Wagner, Regelsbach (DE); Andreas Wolter, Regensburg (DE); Sonja Koller, Regensburg (DE); Vishnu Prasad, Putzbrunn (DE)

(21) Appl. No.: 15/475,368

(22) Filed: Mar. 31, 2017

(51) Int. Cl. G06F 1/20; H05K 7/20; G06F 1/18

(52) U.S. Cl. CPC G06F 1/20; H05K 7/2029; G06F 1/181; H05K 7/2039; H05K 7/20336

(57) ABSTRACT

An electronic component assembly includes a substrate having a first face and an opposed second face. One or more electronic components are coupled with either or both of the first and second faces. A filler interface heat transfer system is coupled with the substrate. The filler interface heat transfer system includes at least one enclosure shell coupled with one of the first or second faces. The at least one enclosure shell surrounds a filler cavity including the one or more electronic components therein. A heat transfer filler is within the filler cavity, the heat transfer filler includes a contoured filler profile conforming to at least the one or more electronic components.

### TECHNICAL FIELD

This document pertains generally, but not by way of limitation, to heat management of electronic devices.

### BACKGROUND

Electronic devices including smart phones, tablet computers, laptops, two in one devices, desktop computers and the like include various electronic components that generate heat. These devices include features configured to extract heat from the electronic components.

In some examples, electronic devices include conductive heat pipes. The heat pipe is mechanically bonded at one end to an electronic component, and the heat pipe is routed through the electronic device to an exterior interface, such as the device housing. The heat pipe is mechanically bonded at its opposed end to the exterior interface. In some examples, the heat pipe is solid and constructed with a material having a high thermal conductivity, such as copper. In other examples, the heat pipe includes a passage filled with a fluid. In each case, the solid heat pipe or fluid filled heat pipe transfers heat from mechanical bond with the electronic component to the opposed mechanical bond at the exterior interface.

Other electronic devices include heat pipe systems including refrigeration circuits that circulate a chilled fluid between an evaporator at a heat generating electronic component to a thermal diffusion plate that serves as a condenser. The refrigeration circuit is routed through the device and remotely positions the thermal diffusion plate relative to the evaporator and the electronic component.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a perspective view of one example of an electronic device including a device housing.

FIG. 2 is schematic view of the device of FIG. 1 with a portion of the device housing removed to reveal components of the device.

FIG. 3 is a perspective view of a substrate including a plurality of components coupled with the substrate.

FIG. 4A is a perspective of one example of a filler interface heat transfer system coupled with the substrate.

FIG. 4B is another perspective view of the filler interface heat transfer system coupled with the substrate of FIG. 4A.

FIG. 5A is a perspective of another example of a filler interface heat transfer system coupled with the substrate.

FIG. 5B is another perspective view of the filler interface heat transfer system coupled with the substrate of FIG. 5B.

FIG. 6 is a cross sectional view of a filler interface heat transfer system coupled with a device housing.

FIG. 7 is a perspective view of a filler interface heat transfer system coupled with at least one heat pipe.

FIG. 8 is a perspective view of a filler interface heat transfer system coupled with a heat pipe refrigeration circuit.

### DETAILED DESCRIPTION

The present inventors have recognized, among other things, that a problem to be solved includes overcoming throttled heat transfer from one or more electronic components through heat pipes. A heat pipe provides a connection to an exterior of the device, heat sink or the like having a relatively small profile compared to the component profile of the electronic component it is coupled with. The small profile of the heat pipe throttles heat transfer from the heat generating component, for instance to a device exterior. Alternatively, a heat pipe having a large profile is coupled with the electronic component. The large profile heat pipe is then routed through the device to a vent, thermal diffusion plate (e.g., a condenser) or an exterior interface. The large profile heat pipe consumes valuable space otherwise used by device components (e.g., processor, memory, antennas, cameras, batteries or the like) or requires the enlarging of a device having a specified smaller profile (common in the smart phone and tablet industries). Routing of the large profile heat pipe, for instance from the electronic component to an exterior interface or a condenser, further escalates the consumption of space.

The present subject matter provides a solution to this problem with a filler interface heat transfer system. The filler interface heat transfer system includes one or more enclosure shells that encapsulate one or more heat generating electronic components within a filler cavity of the shell. In one example, the one or more heat generating electronic components are installed on a substrate, such as a printed circuit board (PCB), and the one or more enclosure shells are coupled with the substrate. A heat transfer filler (e.g., a fluid at least at delivery to the cavity) fills the filler cavity and conforms to the profile of the one or more electronic components and the enclosure profile of the filler cavity (and the substrate if the shell is coupled thereon). The conforming heat transfer filler provides an intimate interface between the heat generating electronic components and the filler, and the filler further provides an intimate interface with the enclosure shell. Because the heat transfer filler conforms (e.g., shapes, contours, follows, surrounds, encapsulates, envelopes, assumes the shape of the components or the like) to the components 400 the interfaces are large compared to the mechanical connections between heat pipes and electronic components and accordingly minimize throttling of heat transfer through heat pipes. The heat transfer filler thereby readily absorbs and distributes (e.g., spreads) heat from the heat generating electronic components throughout the filler and the enclosure shell. Accordingly, heat is readily spread away from the electronic components by the filler interface heat transfer system to minimize (e.g., minimize or eliminate) localized hot spots within and on a device while also decreasing the heat load at the components.

Optionally, the enclosure shell is coupled with the device housing to transfer heat from the filler interface heat transfer system to the device exterior. For instance, in one example the enclosure shell includes an exterior profile in surface to surface contact with the device housing. The surface to surface contact facilitates rapid heat transfer from the system to the device exterior without the throttling found in other features, such as heat pipes. In other examples, the enclosure shell provides an exterior profile larger than a component profile of the electronic components. One or more heat pipes are readily coupled with the exterior profile and more easily routed to the device housing, a condenser or the like because of the flexibility of coupling and routing provided by the larger exterior profile of the enclosure shell. Additionally, one or more of a greater quantity of heat pipes or larger heat pipes are coupled with the enclosure shell because of the larger exterior profile compared to the smaller component profile of the one or more electronic components within the enclosure shell.

In still other examples, the heat transfer filler include a phase change material configured to change phase when heated. As the electronic components within the enclosure shell generate heat the heat transfer filler gradually changes phase (e.g., from solid to fluid). Temperature increases otherwise caused by the electronic components are instead buffered (e.g., delayed) by the changing state of the heat transfer filler. Accordingly, the device housing (e.g., of a tablet or smartphone) remains relatively cool even while conducting heat intensive processes including but not limited to, streaming video, playing a game, conducting a call or the like.

This overview is intended to provide an overview of subject matter of the present patent application. It is not intended to provide an exclusive or exhaustive explanation of the disclosure. The detailed description is included to provide further information about the present patent application.

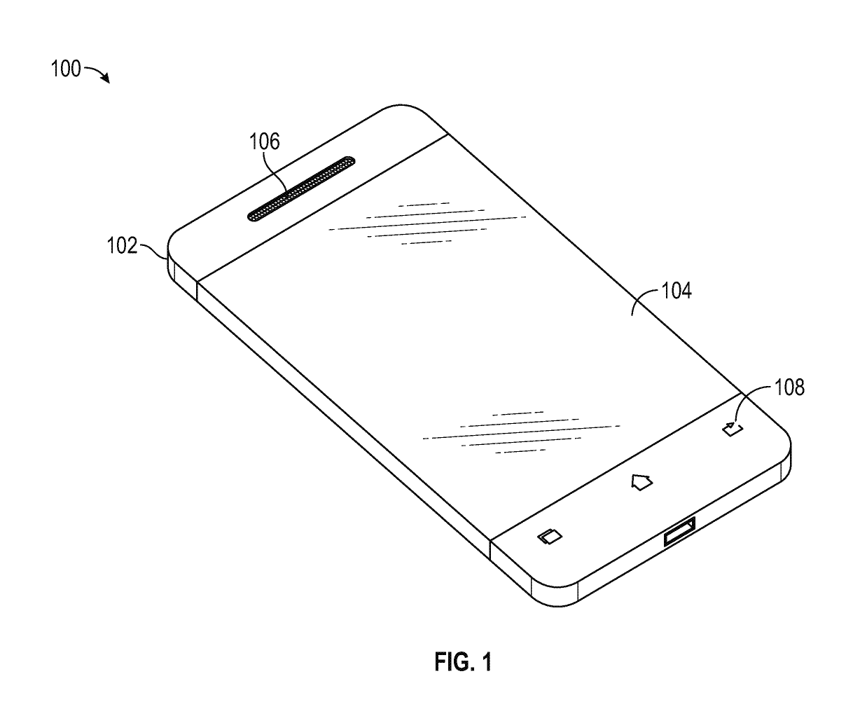

FIG. 1 shows one schematic example of an electronic device 100. The electronic device 100 provided in FIG. 1 is, in one example, a mobile phone. In other examples, the electronic device 100 includes, but is not limited to, one or more of a mobile phone, a tablet, a smartphone, a laptop, two-in-one device, desktop computer, server node or the like. Referring again to FIG. 1, the electronic device (hereinafter device) 100 includes a device housing 102 and one or more inputs. One input includes the screen 104, in an example where the screen 104 is a touch screen. The device 100 further includes one or more buttons such as input buttons 108 provided on the device housing 102. As further shown in FIG. 1, the device 100 further includes one or more audio outputs or inputs such as the audio output 106 provided at one end of the device housing 102. In another example, the electronic device 100 includes other audio outputs, for instance, stereo outputs at the opposed end of the device housing 102. Optionally, other inputs for the electronic device 100 include, but are not limited to, microphones, sockets such as USB sockets, micro USB sockets, or the like.

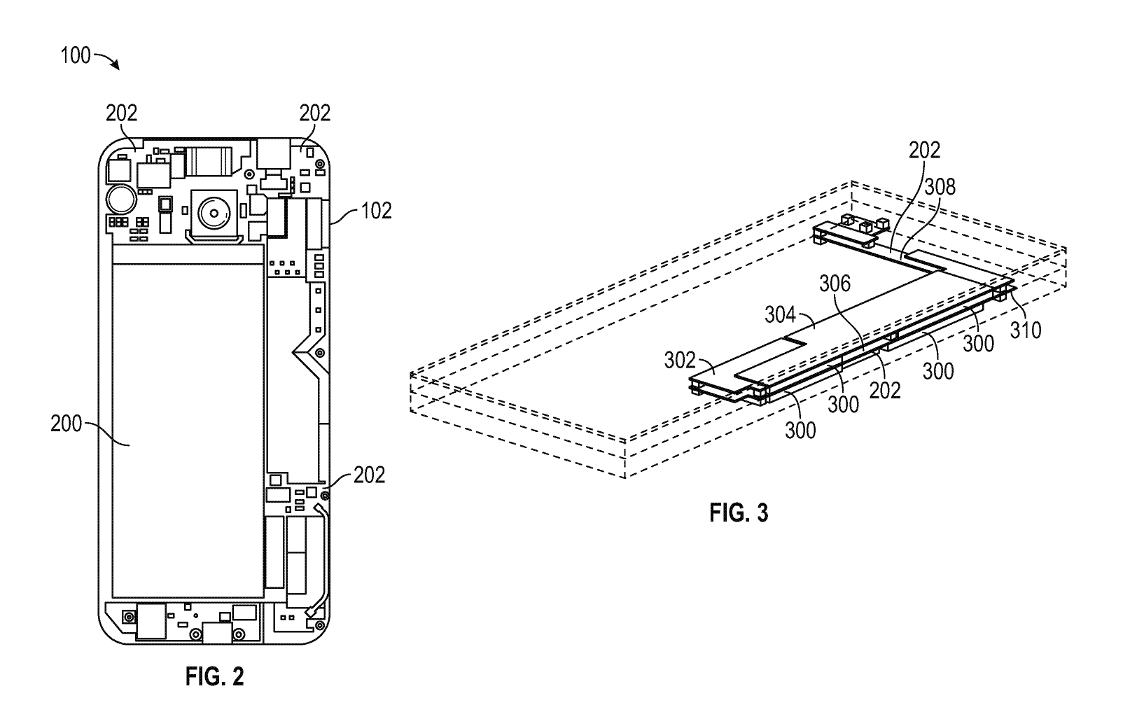

Referring now to FIG. 2, the device 100 previously shown in FIG. 1 is provided in an open configuration, for instance, with a portion of the device housing 102 removed to reveal components within the device 100. As shown in FIG. 2, the device 100 includes a power source 200, in one example, a battery positioned within the device housing 102. As further shown, the substrate 202 (e.g., a printed circuit board or other substrate) is also provided within the device housing 102. The substrate 202 is provided, in one example, in a conforming shape relative to the power source 200. For instance, the substrate 202 is provided within the portions of the device housing 102 that do not include the power source 200. In the example shown in FIG. 2, the substrate 202 wraps around or extends around the power source 200 and, accordingly, fills the space not otherwise occupied by the power source 200. As will be described herein, the substrate 202 includes a plurality of electronic components thereon configured to provide one or more functions to the device 100. The electronic components include, but are not limited to, one or more of memory, processers, RAM, and hardware components such as cameras, microphones, LEDs, lights or the like.

FIG. 3 shows a perspective view of the substrate 202 in a perspective view with the device housing 102 and other components of the device 100 removed. As shown, the substrate 202 has a complementary shape relative to the power source 200 to facilitate the fitting of each of the substrate 202, its components thereon as well as the power source 200 within the device housing 102.

Referring again to FIG. 3, the substrate 202 is shown as a multi-layer element including one or more components thereon. For instance, the substrate 202 extends in an L or dog leg fashion and includes electronic components on one or more of these portions of the substrate 202. Protective features such as protective sleeves 302 are optionally provided on the substrate 202 and provide one or more structural components configured to protect fragile or delicate components coupled with the substrate 202 including, but not limited to, wiring or cables. As further shown in FIG. 3, a plurality of casings 300 are provided on the substrate 202, for instance, on one or more of first and second surfaces 308, 310 of the substrate 202. As will be described herein, one or more electronic components are optionally installed on the substrate 202 on either of the first or second surfaces 308, 310. Where these components are fragile, require protection or the like, in one example, the casings 300 enclose these components and provide a protective frame or other structural support configured to protect these components, for instance, while the electronic device 100 is stored, for instance, within a pocket, backpack, briefcase, purse or the like. Optionally, the casings 300 further provide one or more other functions including, for instance, electromagnetic interference shielding to the components therein.

Referring again to FIG. 3, as shown, the substrate 202 is covered in one example by an electromagnetic interference (EMI) shield 304 provided over one or more surfaces of the substrate 202, for instance, over one or more of the casings 300. The EMI shield 304 provides electromagnetic interference shielding to each of the components adjacent to or underlying each of the shields 304. As shown in FIG. 3, the EMI shield 304 is provided, in one example, above the first surface 308. In other examples, a second EMI shield 304 is provided beneath the substrate 202, for instance, along one or more of the components coupled with the second surface 310, such as the casings 300. Optionally, the shields 300 are applied to the casings 300 as adhesive membranes. In other examples, the shields 300 are integral components to the casings 300.

As previously described, one or more of electronic components, casings 300, EMI shields 304, protective sleeves 302 or the like are coupled along the substrate 202, for instance, along one or more of the first or second surfaces 308, 310 (e.g., opposed surfaces as shown in FIG. 3). These components are coupled with features of the substrate 202, for instance, with leads, conductive traces or the like provided along the substrate 202. Coupling is provided with, but not limited to, one or more of soldered connections, soldered interfaces, adhesives, mechanical interference fits, mechanical fittings such as clamping or crimping, or the like to provide secure connections between these components and the substrate 202.

As further shown in FIG. 3, the substrate 202, in one example, includes a utility slot 306, for instance, provided between one or more of the casings 300. The utility slot 306 provides a conforming plug, socket or the like therein configured for reception of a corresponding plug, socket or card, for instance, a memory card, SIM card or the like used with an electronic device 100. In other examples, the utility slot 306 provides a socket for coupling with one or more cables or cords, for instance, a power cord, data and power cord, data cord, headphone cable or the like.

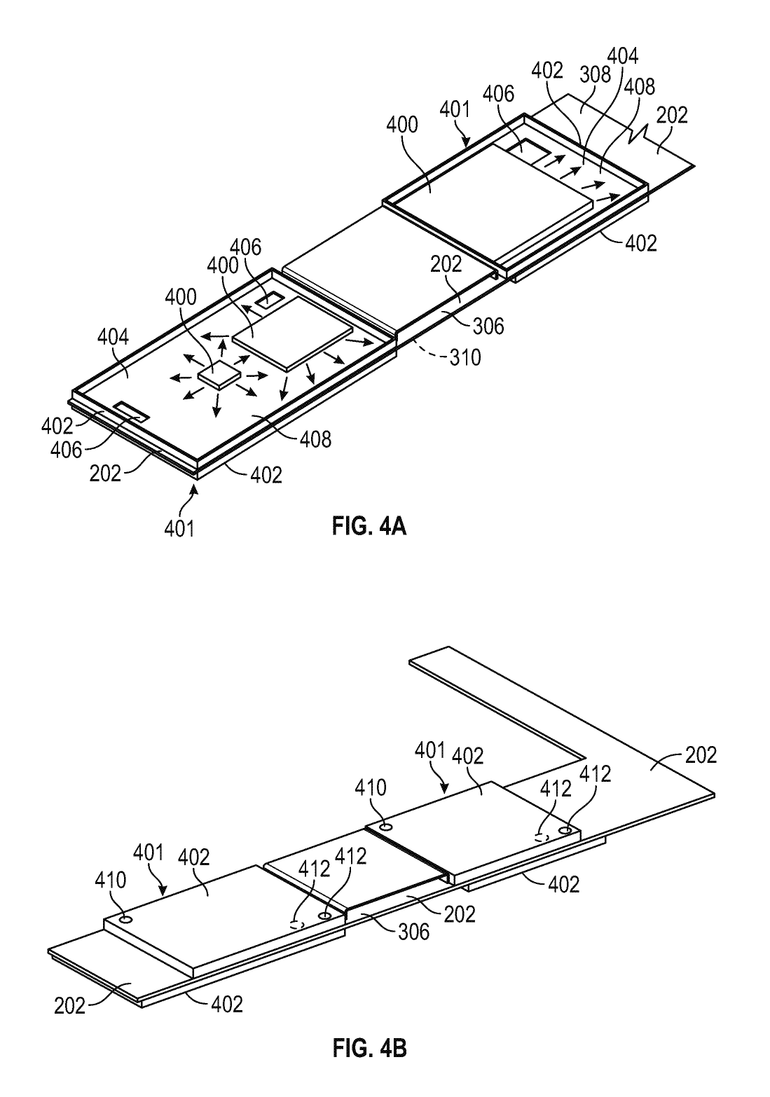

FIGS. 4A and 4B show one example of the substrate 202 including a filler interface heat transfer system 401. As will be described herein, the filler interface heat transfer systems include one or more enclosures such as enclosure shells extending around one or more electronic components 400. The enclosure shells 402 include filler cavities having a heat transfer filler 408, such as a fluid or phase change material therein. The heat transfer filler provides a conforming profile relative to each of the electronic components 400. For instance, the heat transfer filler 408 extends around and is in intimate contact with each of the electronic components 400 within each of the enclosure shells 402. Accordingly, the heat transfer filler 408 provides for distributed heat transfer away from each of the electronic components 400 and into the heat transfer filler 408 along a distributed heat path ((shown with the multi-direction arrows in FIG. 4A) from the electronic components 400 through the filler 408 into the enclosure shells 402 for eventual disbursement whether within the device 100 or through one or more interfaces of the filler interface heat transfer system 401 with vents, heat sinks, heat pipes or the like coupled with the device housing such as the device housing 102 (shown in FIGS. 1 and 2). Accordingly, the heat generated by the one or more electronic components is readily distributed into the heat transfer filler 408 in a distributed fashion and then collected and disbursed outside of the device such as the electronic device 100 shown in FIGS. 1 and 2.

Referring first to FIG. 4A, a detailed perspective view of the substrate 202 including a plurality of electronic components 400 coupled there along is provided. As shown, each of the electronic components 400 are coupled with the substrate 202, for instance, by one or more of adhesives, mechanical fittings, soldering or the like. As shown, the electronic components 400 are housed or retained within filler cavities 404 of one or more enclosure shells 402. The enclosure shells 402 are coupled with the substrate 202. The enclosure shells 402 extend around each of the electronic components 400 and thereby isolate each of the electronic components 400 (when the enclosure shells 402 are closed) relative to the remainder of the components within the device 100 including, but not limited to, the power source 200, other electronic components, the remainder of the substrate 202 not within the shells 402, mechanical components or the like.

As further shown in FIG. 4A, in this example, a plurality of enclosure shells 402 are provided at differing locations along the substrate 202. For instance, enclosure shells 402 are provided on the first and second surfaces 308, 310 at opposed positions in this example. In one example, the enclosure shells 402 are coupled with the substrate 202 with an adhesive coupling provided along the edges of the enclosure shells 402 and the corresponding portions of the substrate 202. In other examples, the enclosure shells 402 include metal enclosure shells 402. Accordingly, one or more of welding, soldering or the like is used to couple the enclosure shells 402 with the substrate 202. When coupled with the substrate 202 the enclosure shells 402 and the substrate from provide a sealed filler cavity 404 for the electronic components 400. In still other examples, the enclosure shells 402 are coupled across one or more substrates 202. For instance, the enclosure shell 402 is coupled with component substrates 202 (with portions of the substrates proximate each other) and the shell encapsulates electronic components 400 provided on each of the substrates. The enclosure shell 402 bridges between the substrates 202 and encloses the components 400 and portions of the substrates 202 to provide a filler cavity 404 for the reception of the heat transfer filler 408. Optionally, the enclosure shell 402 is coupled over the first and second surfaces 308, 310. For instance, the enclosure shell 402 wraps around the first and second surfaces 308, 310 and components 400 thereon and the filler cavity 404 extends between the upper and lower portions (proximate the first and second surfaces 308, 310) of the enclosure shell.

The enclosure shells 402 are shown in an open configuration. In other examples (see FIG. 4B) the enclosure shells 402 are coupled over top of the electronic components 400 in a closed configuration to thereby enclose each of the electronic components 400 within the respective filler cavities 404 of each of the shells 402. The enclosure shells 402 are optionally constructed with one or more materials having a relatively high thermal conductivity (e.g., greater than 200 W/mK, greater than 350 W/mK, or the like). For instance, the enclosure shells 402 are constructed with, but are not limited to, one or more of stainless steel; copper; silver; alloys, such as a nickel silver alloys, copper alloys; aluminum or the like. Optionally, the enclosure shells are constructed with materials having enhanced corrosion resistance including polymers, such as plastics, rubbers or the like. In other examples, the polymers are doped with heat conducting components including metallic filings, particles or the like. In still other examples, the enclosure shells 402 are constructed with materials having lower thermal conductivities (e.g., less than 200 W/mK). In some of these examples, the enclosure shells 402 include one or more inserts or zones having a higher thermal conductivity relative to the remainder of the shell to enhance heat transfer from the enclosure shells and the heat transfer filler 408 (e.g., to a heat pipe, vent or the like).

As further shown in FIG. 4A, each of the enclosure shells 402 includes a heat transfer filler 408 within the filler cavity 404 of each of the enclosure shells 402. The heat transfer filler 408 is provided to the filler cavity 404, in one example, in a liquid form. For instance, the liquid heat transfer filler 408 is provided through one or more ports and fills the filler cavity 404 to provide an intimate engagement between the filler 408 and the one or more electronic components 400 as well as the enclosure shell 402. For instance, in one example, where the heat transfer filler 408 is delivered in a liquid form to the filler cavity 404 the heat transfer filler 408 flows around the components 400 and along any other features in the filler cavity 404. The heat transfer filler 408 has a contoured filler profile that conforms around each of the electronic components 400 as well as the portion of the substrate 202 within the respective enclosure shell 402. Further, the heat transfer filler 408, having the contoured filler profile conforms to an enclosure profile, for instance of the interior of the enclosure shell 402. Accordingly, intimate contact between the electronic components 400 within each of the enclosure shells 402 and the enclosure shell 402 itself is facilitated by the heat transfer filler 408 having the corresponding configuration with each of the components of the shell 402 and the electronic components 400. The intimate contact of the heat transfer filler 408 with the electronic components 400 and the enclosure shell 402 enhances the distributive heat transfer from the components 400 because of the consistent and relatively large interfaces between each of the components 400, substrate 202, filler 408 and the enclosure shells 402.

In another example, and as shown in FIG. 4A, the filler interface heat transfer system 401 optionally includes one more filler communication ports 406 provided between two or more of the enclosure shells 402. In the example shown in FIG. 4A, the enclosure shells 402 provided on the first surface 308 are in communication with the enclosure shells 402 provided along the second surface 310 by way of the filler communication ports 406 extending through the substrate 202. The intercommunication between the enclosure shells 402 facilitates the transfer of heat, for instance, from the electronic components 400 in one of the enclosure shells to the heat transfer fluid 408 in another enclosure shell such as a lower enclosure shell provided along the second surface 310. Accordingly, heat is not only distributed in a lateral fashion, for instance, through the heat transfer filler 408 to the periphery of the filler cavities 404 and the enclosure shell 402. Instead, with the filler communication ports 406 heat is also transferred to other components of the filler interface heat transfer system 401 including other volumes of heat transfer filler 408 in enclosure shells 402 in communication with the first enclosure shell 402 including the heated electronic component 400. In one example, for instance where the electronic components 400 shown in the enclosure shell 402 provided to the left of FIG. 4A are operated over a long period of time, strenuously or both heat is generated by the electronic components 400 and distributed through the heat transfer filler 408, for instance, in a distributed fashion away from the electronic components 400. The filler communication ports 406 are provided to other enclosure shells 402. The heat transfer from the electronic components 400 is further distributed to these other enclosure shells 402 and the heat transfer filler 408 therein. Accordingly, localized hot spots caused by strenuous or longtime use of components 400 are minimized (e.g., decreased or eliminated) as heat from the components 400 is transferred throughout the device, for instance, throughout the filler interface heat transfer system 401. The inclusion of filler communication ports 406 further enhances the distribution of heat. Devices including the filler interface heat transfer system 401 are thereby configured to operate at cooler temperatures for longer periods of time.

Additionally, because the heat transfer filler 408 (e.g., a liquid or phase change material, in some examples) conforms to each of the electronic components 400 and the substrate 202 as well as the enclosure shells 402 an intimate interface is provided between each of these components to facilitate reliable and enhanced heat transfer from the electronic components 400. For instance, the heat transfer filler 408 includes a contoured filler profile greater than the corresponding profile of each of the electronic components 400. The contoured filler profile extends along the component profile of each of the electronic components 400. Further, the contoured filler profile is also intimately engaged with the substrate 202. In one example, the substrate 202 within the respective enclosure shells 402 and the electronic components 400 have a composite profile matching the corresponding component profiles of the electronic components 400 and the substrate profile of the substrate 202 within the enclosure shell 402. Further, in other examples, the contoured filler profile extends along and conforms to an enclosure profile of the enclosure shell 402. Accordingly, the heat transfer filler 408 provides intimate heat conductive contact between each of the electronic components 400, the filler itself 408 as well as other components of the filler interface heat transfer system 401 including, for instance the enclosure shells 402. This intimate and conforming contact between these features provides a distributed heat path that facilitates the transfer of heat away from electronic components 400 and accordingly facilitates the operation of the device 100 at cooler temperatures and with minimized localized hot spots when compared to electronic components 400 otherwise generating heat and transferring heat by radiation, conduction to the air in the device, or throttled conduction through discretely coupled heat pipes.

Referring now to FIG. 4B, a perspective view of the substrate 202 and the filler interface heat transfer system 401 shown in FIG. 4A is provided. In this example, the enclosure shells 402 are shown in the closed configuration along with one or more ports configured to facilitate the filling and venting of the enclosure shells 402. For instance, in the example shown in FIG. 4B, each of the enclosure shells 402 includes at least one filler inflow port 410 provided at one location within the enclosure shells 402. Additionally, the enclosure shells 402 include one or more relief ports 412 that vent gases within the enclosure shells 402, for instance, during filling of the enclosure shells by way of delivery of the heat transfer filler 408 through the filler inflow port 410. For instance, a liquid heat transfer filler 408 is supplied through the filler inflow port 410. The relief port 412 allows for the venting of gas from the enclosure shell 402 and accordingly facilitates the filling of substantially the entire filler cavity 404 of each of the enclosure shells 402.

Optionally, where the enclosure shells 402, for instance, upper and lower enclosure shells 402 are fluidly coupled by the filler communication ports 406 each of the enclosure shells 402 are filled by delivery of the filler to one of the shells and communication of the filler through the port 406 to the other shell 402. In one example, the filler inflow port 410 is provided in a first enclosure shell 402 and the relief port 412 is provided in the other fluidly coupled enclosure shell 402. Accordingly, by filling through the filler inflow port 410 provided in a first enclosure shell 402, the other enclosure shell 402 is also filled at the same time. Although FIG. 4A shows the filler communication ports 406 provided as a feature extending through the substrate 202 in other examples the filler communication ports 406 are provided in a lateral manner as tubes or ducts extending between the enclosure shells 402 provided on one of the surfaces 308, 310 of the substrate 202. For instance, the enclosure shells 402 on the first surface 308 are in fluid communication by way of a filler communication port such as a capillary tube, tube, duct or the like extending between the enclosure shells 402. After filling of the enclosure shells 402 each of the filler inflow ports and relief ports 412 are closed with one or more features including, but not limited to, a valve, weld or solder dot, cap, plug or the like.

The heat transfer filler 408 includes, but is not limited to, one or more compounds such as thermal interface material (TIM), transformer oils, waxes or paraffins, salt-water solutions, salt hydrates, polyglycols, fatty acid, fluorocarbon based fluids or the like. Other example heat transfer fillers 408 include, but are not limited to, organic or non-corrosive fillers that do not damage materials in the device 100 (e.g., the substrate 202, electronic components 400 or the like) over the operational lifetime of the device. In some examples as described herein, the heat transfer filler 408 is a single-phase filler (does not change phase). In other examples described herein, the heat transfer filler 408 is a multiple-phase filler (does change phase) and accordingly provides a temperature buffer that arrests the elevation of temperature at the components 400 while the filler 408 changes phase, for instance from solid to liquid. Some examples of multiple-phase heat transfer fillers 408 include, but are not limited to, one or more of waxes or parafins, fluorocarbon based fluids, thermal interface material, fatty acids (oils), lauric acid, formic acid, caprilic acid, glycerin, p-lactic acid, trimethylolethane (TME), polyglycols, salt hydrates, salt-water solutions or the like.

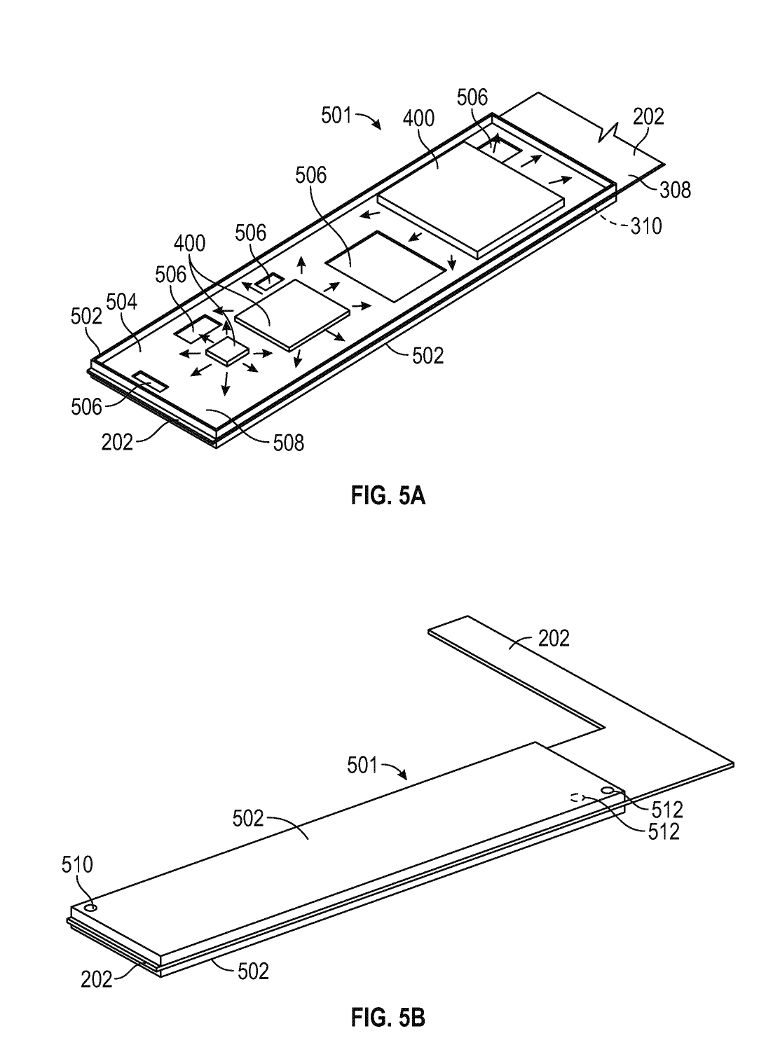

FIGS. 5A and 5B show another example of a filler interface heat transfer system 501. Referring first to FIG. 5A, some of the features shown herein are similar in at least some regards to features previously described and shown, for instance in FIGS. 4A and 4B. The filler interface heat transfer system 501, in this example, is coupled with the substrate 202 such as a printed circuit board or the like provided for an electronic device including, but not limited to, a smartphone, mobile phone, tablet computer, desktop computer, server node or the like. Further, the filler interface heat transfer system 501 includes a plurality of enclosure shells 502 provided one or more of the first and second surfaces 308, 310 of the substrate 202. The enclosure shells 502 are filled, in one example, by the heat transfer filler 508 in a similar manner to the filler interface heat transfer system 401 shown in FIGS. 4A and 4B and previously described herein.

Referring first specifically to FIG. 5A, the filler interface heat transfer system 501 is shown in an open configuration with the top of the enclosure shell 502 provided on the first surface 308 of the substrate 202 removed. As shown, the enclosure shell 502 surrounds (e.g., encapsulates, envelopes, captures or the like) a plurality of electronic components 400 coupled with the substrate 202. In a similar manner to the enclosure shells 402 previously described herein, the enclosure shells 502 each provide a filler cavity 504 configured for the reception of the electronic components 400 and a heat transfer filler 508. In one example, the filler interface heat transfer system 501 further includes an optional enclosure shell 502 provided, for instance, along the second surface 310. In the example shown in FIG. 5A, the enclosure shell 502 provided on the second surface 310 has a matching footprint to the enclosure shell 502 provided on the first surface 308. In another example, the enclosure shells 502 have differing profiles and are accordingly not aligned. For instance, in one example, the enclosure shells 502 on the second surface 310 has a smaller footprint and accordingly underlies a portion of the enclosure shell 502 provided on the first surface 308. In still another example, a plurality of enclosure shells 502 are provided along one or more of the first or second surfaces 308, 310 in a manner similar in at least some regards to the configuration shown in FIG. 4A.

As further shown in FIG. 5A, a heat transfer filler 508 is provided within the filler cavity 504. The heat transfer filler 508 has a contoured filler profile that conforms to the profile of each of the electronic components 400 and fills the filler cavity 504. The heat transfer filler 508 has a contoured filler profile conforming to the enclosure shell 502. As previously described herein, because the heat transfer filler 508 conforms to each of the electronic components 400, the enclosure shell 502 and substrate 202 provides between these features and accordingly facilitates the transfer of heat, for instance, along a distributive heat transfer path (shown with the multi-direction arrows in FIG. 5A) through the heat transfer filler 508 to one or more of the substrate 202, the enclosure shell 502 or the like. The heat transfer filler 508 in combination with the enclosure shell 502 facilitates the distribution of heat from the electronic components 400 into the filler 508 and eventually through the enclosure shell 502 for dispersion outside of the device device 100. In one example, where one or more of the electronic components 400 would otherwise provide a localized hot spot to the device 100, the filler interface heat transfer system 501, including the heat transfer filler 508 and one or more enclosure shells 502 facilitates the distribution of heat away from the electronic components 400 and spreads the heat throughout the system 501. Accordingly, localized hot spots are avoided and the device 100 in at least one example is configured to operate more coolly and therefore more efficiently relative to other devices not including the filler interface heat transfer system 501 (or system 401).

As further shown in FIG. 5A and previously described herein, the filler interface heat transfer system 501 optionally includes one or more filler communication ports 506. The filler communication ports 506 allow for the fluid communication of the heat transfer filler 508, for instance, between one or more enclosure shells 502 such as the enclosure shells provided on the first and second surfaces 308, 310 in the embodiment shown in FIGS. 5A and 5B. Accordingly, heat transfer to the heat transfer filler 508 from the electronic components 400 is, in one example, further distributed within the filler interface heat transfer system 501 to the other enclosure shell 502 and the heat transfer filler 508 provided in the enclosure shell. Further, as described herein, the filler communication ports 506 also facilitate the initialization or initial delivery of the heat transfer filler 508 into the enclosure shells 502 to accordingly fill each of the shells (e.g., their filler cavities 504) during initial assembly of the filler interface heat transfer system 501.

Referring now to FIG. 5B, the enclosure shells 502 are fully enclosed, for instance, with the previously removed tops coupled over the walls of the enclosure shells 502 shown in FIG. 5A. As shown, the filler interface heat transfer system 501 is thereby enclosed to accordingly retain the heat transfer filler 508 therein and isolate the remainder of the device from the heat transfer filler 508.

As further shown in FIG. 5B, the filler interface heat transfer system 501 includes as shown one or more filler inflow ports 510 and one or more relief ports 512. In one example, where the enclosure shell 502 along the first surface 308 is isolated from other enclosure shells, the filler inflow port 510 is used to deliver heat transfer filler 508 into the filler cavity 504 and the relief port 512 vents gases within the enclosure shell 502 while it is filled with the filler 508. In other examples, where one or more filler communication ports 506 are provided between the enclosure shells 502, the delivery of the heat transfer filler 508 is again conducted through a filler inflow port 510, for instance, provided in either of the enclosure shells 502. Optionally, the relief port 512 is provided on an opposed shell (e.g., the bottom shell 502 as shown in FIG. 5B). As the heat transfer filler 508 is delivered through the filler inflow port 510, the heat transfer filler not only moves laterally to fill the filler cavity 504 of the shell 502 provided on the first surface 308, the heat transfer filler 508 also is distributed through the filler communication ports 506 into the second enclosure shell 502 provided along the second surface 310. Providing a relief port 512 in the enclosure shell 502 opposed to the shell having the filler inflow port 510 along the second surface 310 facilitates the filling of the second enclosure shell 502 and accordingly minimizes the retention of gas pockets within the enclosure shells 502.

As previously described above, the filler interface heat transfer system 501 shown, for instance, in FIGS. 5A and 5B, as well as the filler interface heat transfer system 401 shown in FIGS. 4A and 4B is enclosed by way of one or more enclosure shells 502. Optionally, the device 100 is a sealed device, for instance, a sealed smartphone, mobile phone or the like configured to isolate the interior components of the device 100 from exterior fluids such as water. In one example, the interior components of the device 100 sensitive to water are themselves waterproof or sufficiently water resistant to prevent the ingress of the heat transfer filler 508 therein. In such an example, the device housing such as the device housing 102 shown in FIG. 1 is, in one example, used as an enclosure shell, such as the shells 502 shown in FIGS. 5A and 5B or the shells 402 shown in FIGS. 4A and 4B. Accordingly, the heat transfer filler 508 extends beyond the substrate 202, for instance, into the device 100. The contoured filler profile is enhanced (e.g., enlarged) relative to the component profile of the electronic components 400 (shown in FIGS. 4A and 5A) as well as the substrate 202. Accordingly, heat generated by the one or more electronic components 400 is distributed throughout the device 100 by the distributed heat transfer filler 508 therein.

In another example, for instance, where the enclosure shells 402, 502 is surround the electronic components 400, the enclosure shells 502 optionally provide a protective frame around the one or more components 400. For instance, in one example, the enclosure shells 502 provide a dual function. The first function includes protecting the one or more electronic components 400 provided within the enclosure shells 502 in a manner similar to the casings 300 shown in FIG. 3. Additionally, the enclosure shells 402, 502 also enclose and seal the heat transfer filler 508 around the electronic components 400 to facilitate the distributed heat transfer away from the electronic components 400 along the distributed heat path (shown with the multi-direction arrows in FIGS. 4A and 5A). Accordingly, in such an example where the enclosure shells 402, 502 provide both a protective function as well as retention and sealing of the heat transfer filler 508 around the electronic components 400, each of the filler interface heat transfer system 401, 501 consolidates mechanical and structural protection of the electronic components 400 as well as distributed heat transfer for the electronic components 400. In still other examples, the enclosure shells 502 provide additional functions (e.g., three or more) including, for example, electromagnetic shielding for the components 400 housed therein.

As previously described herein, the filler interface heat transfer systems 401, 501 include a heat transfer filler 408, 508 provided within the respective filler cavities 404, 504. The heat transfer filler 408, 508 is, in one example, a fluid provided through one or more filler inflow ports 510 to the filler cavities, such as the filler cavities 504 shown in FIGS. 5A, B and through the filler inflow ports 410 into the filler cavities 404 as shown in FIGS. 4A, B. In one example, the fluid heat transfer filler 508 solidifies after introduction into the filler cavities, for instance, as the heat transfer filler cools after delivery. In another example, the heat transfer filler 408, 508 remains substantially fluid throughout its operational lifetime within the enclosure shells 402, 502. In still other examples, the heat transfer filler 508 includes a multiple phase material (e.g., a phase change material, or PCM) that solidifies after introduction into the enclosure shells 402, 502. During operation of the device 100, for instance, operation that causes the electronic components 400 to generate heat, the heat transfer filler 408, 508 is heated by the components 400 and goes through a phase change (e.g., from solid, to liquid and solid slurry, to liquid). The change in phase act as a temperature buffer and absorbs a significant amount of heat from each of the electronic components 400 without otherwise raising the temperature of the heat transfer filler 408, 508. Accordingly, the filler interface heat transfer systems 401, 501 with a phase change material are able to substantially decrease the heat distributed to the device housing 102 while the heat transfer filler 408, 508 experiences the phase change. Accordingly, for the user operating the device 100, for instance, a mobile phone, smartphone, tablet, two-in-one device or the like, the device remains cool during operation. In some examples, by using a phase change material as the heat transfer fillers 408, 508 the user detects little or no heating of the device 100 (e.g., the device housing 102) even under strenuous or longterm operation because heat is absorbed by the phase change in the heat transfer fillers 408, 508.

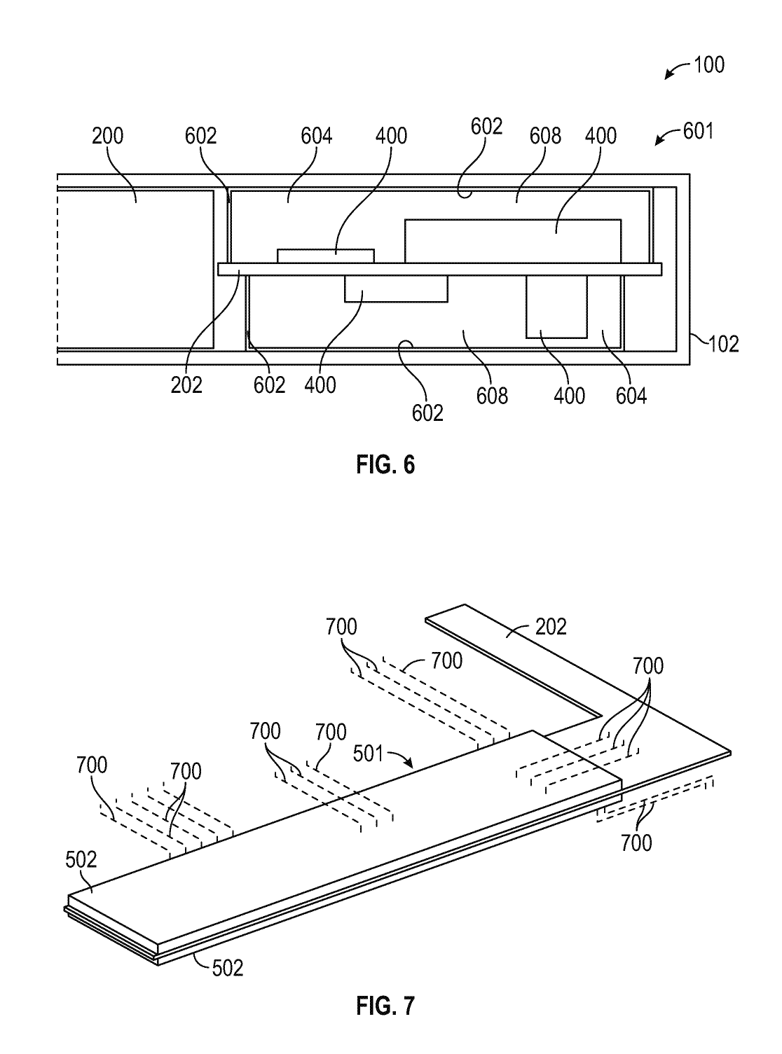

FIG. 6 shows a partial cross-sectional view of a device, such as the electronic device 100. In this example, the electronic device 100 includes the power source 200 (partially shown in this detailed cross-sectional view) as well as a filler interface heat transfer system 601. The filler interface heat transfer system 601 includes similar components to the previously described filler interface heat transfer systems 401, 501 described herein. For instance, the system 601 includes one or more enclosure shells 602 surrounding one or more corresponding electronic components 400. As shown in FIG. 6, the enclosure shells 602 are fastened to the substrate 202, for instance, by one or more of adhesives, soldering, mechanical fittings or the like. The enclosure shells 602 receive a heat transfer filler 608 within the respective filler cavity 604 and provide a sealed environment for retention of the filler therein.

The heat transfer filler 608 (e.g., phase change material, heat transfer fluid or the like) is in intimate contact with each of the electronic components 400. The heat transfer filler 608 has a contoured filler profile that conforms to the shapes of the electronic components 400. For instance, when delivered to the filler cavity 604, the heat transfer filler 608 is provided in a liquid form and accordingly conforms to the shape of each of the electronic components 400, the substrate 202 as well as the enclosure shell 602. A profile of the heat transfer filler 608, a contoured filler profile, is greater than the corresponding profile of the electronic components 400 (a component profile). In one example, the contoured filler profile is greater than the component profile of the electronic components 400 as well as the substrate profile of the underlying substrate 202. Because the heat transfer filler is in intimate contact and remains in intimate contact with the electronic components 400 as well as the underlying substrate 202 heat generated from the electronic components and conductively transmitted into the substrate 202 is accordingly distributed into the heat transfer filler 608, for instance, along a distributive heat path. The heat transferred into the heat transfer filler 608 is broadcast throughout the filler and accordingly conducted to the enclosure shell 602. As previously described, the distributive heat path facilitates the distribution of heat from the electronic components 400 into the remainder of the filler interface heat transfer system 601 to accordingly minimize localized hot spots within the device 100 and provide for a relatively cooler operating device 100 compared with other devices that do not include additional heat mitigation measures.

As further shown in FIG. 6, the filler interface heat transfer system 601 including, for instance, the enclosure shell 602 is coupled with a feature of the device 100, for instance, the device housing 102. In the example shown in FIG. 6, the enclosure shells 602 of the system 601 are coupled in surface-to-surface contact with the device housing 102. Accordingly, the filler interface heat transfer system 601 has a large surface area and surface-to-surface contact with a corresponding large surface area of the device housing 102. Heat transfer between the filler interface heat transfer system 601 and the device housing 102 to the exterior of the device 100 is thereby facilitated. For instance, a conductive surface-to-surface interface is provided from the heat transfer filler 608 to the one or more enclosure shells 602 and from the enclosure shells 602 to the corresponding portions of the device housing 102. Accordingly, localized heat generated at the electronic components 400 is distributed throughout the system 601 and then correspondingly distributed from the enclosure shells 602 through the surface-to-surface engaged portions of the device housing 102.

FIG. 7 shows a perspective view of components of the device 100 including, for instance, the filler interface heat system 501 coupled along the substrate 202. In the example shown in FIG. 7, a plurality of heat pipes 700 are shown bonded to the enclosure shells 502 of the filler interface heat transfer system 501. The plurality of heat pipes 700 are shown in various configurations and locations relative to the enclosure shells 502 to illustrate the flexibility of coupling and navigation of heat pipes 700 from the overall large profile of the enclosure shells 502 (compared to the component 400 profiles). In contrast, where heat pipes are otherwise coupled with electronic components directly, the electronic components are relatively small and accordingly provide a small profile to couple and extend the heat pipes from. The heat pipes extending from the components are, in at least some examples, tortuously navigated through the device to corresponding vents, radiators, housings or the like for the device.

As shown in FIG. 7, the connection points for the heat pipes 700 to the enclosure shells 502 (e.g., points of bonding or fastening to the shells 502) are flexibly provided at almost any location along the enclosure shells 502. In one example, where the enclosure shells 502 extend over a large portion of the substrate 202 the locations for fastening of the one or more heat pipes 700 are correspondingly more flexible. Further, because the enclosure shells 502 are provided at one or more locations on the substrate 202, for instance, on the first and second surfaces 308, 310, the corresponding heat pipes 700 for each of these enclosure shells 502 are thereby flexibly positioned for each of the enclosure shells 502. Additionally, in other examples, because of the large profile of the enclosure shells (relative to the components 400) one or more heat pipes 700 have a distributed coupling with the enclosure shells 502 (or 402). For instance, the heat pipes are coupled in one or more passes (e.g., in a serpentine, spiral pattern or the like) across the enclosure shells 502 to enhance the area of the interface between the heat pipes and the shells 502.

In another example, for instance, where the filler interface heat transfer system 501 includes one or more filler communication ports 506, the heat transfer filler 508 (shown in FIG. 5A) is in communication between each of the enclosure shells 502. In such an example, the heat pipes 700 shown in FIG. 7 are optionally provided on one of the enclosure shells 502. Because heat transfer is provided between each of the enclosure shells 502 by the fluidly communicated heat transfer filler 508, the heat generated in the opposed enclosure shell 502 not having heat pipes 700 is accordingly transmitted into the enclosure shell 502 including the heat pipes 700. Accordingly, the heat pipes 700 bonded with the enclosure shell 502 are flexibly positioned thereon and leave the opposed enclosure shell 502 free of any heat pipes. Accordingly, the device 100 including, for instance, the filler interface heat transfer system 501 (or 401) is able to flexibly position and navigate one or more heat pipes such as the heat pipes 700 shown herein from one or more locations on the enclosure shells 502 (or 402) to any nearby or remote location within the device 100.

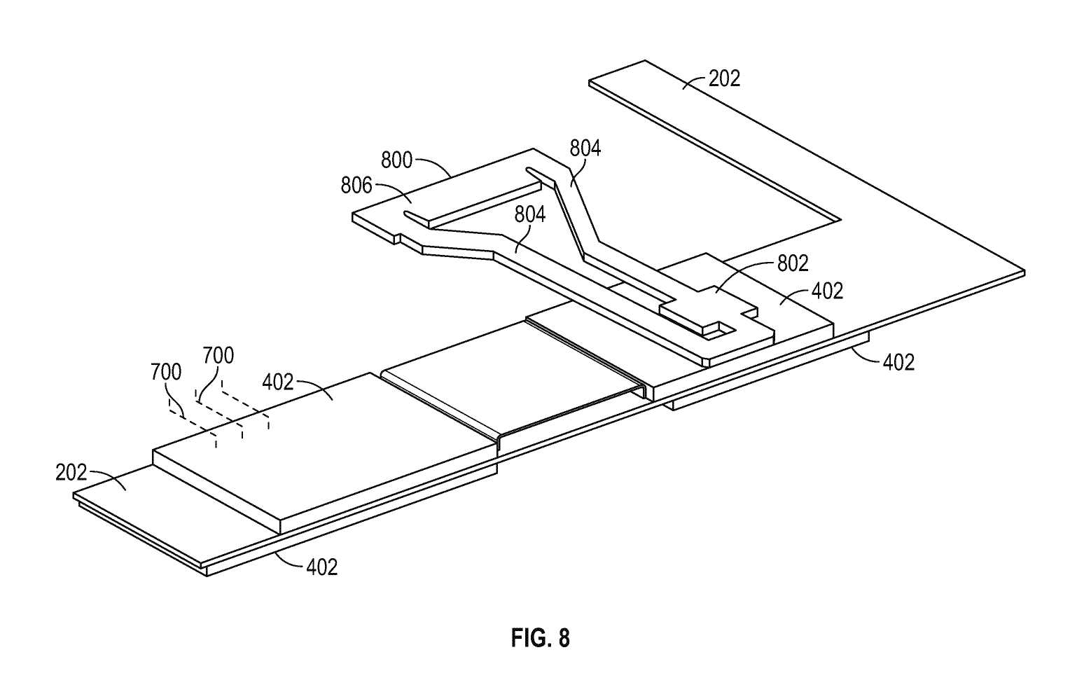

FIG. 7 shows a variety of example heat pipe configurations to illustrate the flexibility of positioning provided with the systems 401, 501, 601. While a plurality of heat pipes 700 are shown, in other examples a single or one or more heat pipes 700 are coupled with one or more enclosure shells 402, 502, 602 to conduct heat from the fillers and shells, for instance to a vent, device housing 102 or the like. Additionally, the heat pipes 700 described herein include, but are not limited to, solid tubes, filaments, ducts or the like extending from the shells 402, 502, 602 to another feature such as a refrigeration circuit (see FIG. 8), device housing 102, vent, radiator, heat sink or the like). In other examples, the heat pipes include tubular structures including a heat transfer fluid therein (e.g., as an example one or more of the fluids used as the heat transfer fillers 408, 508, 608, such as TIM).

FIG. 8 shows another example of the filler interface heat transfer system 401 previously described and shown in FIGS. 4A and 4B. As previously described, the filler interface heat transfer system 401 includes one or more enclosure shells 402 provided on one or more of the first and second surfaces 308, 310 of the substrate 202. In this example, one or more of the enclosure shells 402 includes one or more heat pipes 700 extending from an enclosure shell 402 provided on the first surface 308 of the substrate 202. The example further includes a heat pipe refrigeration circuit 800 (another example of a heat pipe) extending from another enclosure shell 402 also provided in this example on the first surface 308 of the substrate 202.

The heat pipe refrigeration circuit 800 includes a heat pipe loop 804 and one or more heat transfer fluids provided within the heat pipe loop 804 to facilitate the refrigeration (cooling) of the enclosure shells 402 and transfer heat from the filler interface heat transfer system 401 associated with the enclosure shells 402 to the right in the drawing of FIG. 8. In the example shown in FIG. 8, the heat pipe refrigeration circuit 800 includes an evaporator 802 coupled along a surface of the enclosure shell 402 provided on the first surface 308 of the substrate 202. The evaporator 802 receives a heat transfer fluid, for instance, from a vent plate 806 (e.g., a thermal vent plate), and the heat transfer fluid absorbs heat distributed from the system 401 through the enclosure shell 402 and the evaporator. The heat transfer fluid continues moving, for instance, through the heat pipe loop 804 in a clockwise fashion to the vent plate 806. At the vent plate 806, heat absorbed at the evaporator 802 is disbursed, for instance, through one or more vents, direct couplings with the device housing 102 or the like. After cooling at the vent plate 806, the heat transfer fluid is provided again through the heat pipe loop 804 to the evaporator 802 to continue the refrigeration cycle.

### VARIOUS NOTES & EXAMPLES

Example 1 can include subject matter such as an electronic device comprising: a device housing; a substrate within the device housing and coupled with the device housing; one or more electronic components coupled with the substrate, the one or more electronic components and the substrate include a composite profile; and a filler interface heat transfer system coupled with the one or more electronic components, the filler interface heat transfer system includes: at least one enclosure shell coupled with the substrate, the at least one enclosure shell surrounds a filler cavity, the one or more electronic components and the composite profile, a heat transfer filler within the filler cavity, the heat transfer filler includes a contoured filler profile conformed along and engaged along the composite profile, and a distributive heat path including the heat transfer filler and the at least one enclosure shell, the distributive heat path is configured to distribute heat from the one or more electronic components into the heat transfer filler and the at least one enclosure shell and transfer heat from the heat transfer filler and the at least one enclosure shell to the device housing.

Example 2 can include, or can optionally be combined with the subject matter of Example 1, to optionally include wherein the heat transfer filler consists of one of a phase change material or a heat transfer fluid.

Example 3 can include, or can optionally be combined with the subject matter of one or any combination of Examples 1 or 2 to optionally include wherein the at least one enclosure shell is coupled with the device housing.

Example 4 can include, or can optionally be combined with the subject matter of one or any combination of Examples 1-3 to optionally include wherein the at least one enclosure shell is coupled in surface to surface contact with the device housing.

Example 5 can include, or can optionally be combined with the subject matter of one or any combination of Examples 1-4 to optionally include wherein the at least one enclosure shell is coupled with the device housing with one or more heat pipes.

Example 6 can include, or can optionally be combined with the subject matter of Examples 1-5 to optionally include wherein the at least one enclosure shell seals the heat transfer filler within the filler cavity and isolates the remainder of the device housing from the heat transfer filler.

Example 7 can include, or can optionally be combined with the subject matter of Examples 1-6 to optionally include wherein the one or more electronic components include a component profile and the contoured filler profile is greater than the component profile.

Example 8 can include, or can optionally be combined with the subject matter of Examples 1-7 to optionally include wherein contoured filler profile is conformed along and engaged along an enclosure profile of the at least one enclosure shell.

Example 9 can include, or can optionally be combined with the subject matter of Examples 1-8 to optionally include wherein the at least one enclosure shell includes a protective frame surrounding at least the one or more electronic components.

Example 10 can include, or can optionally be combined with the subject matter of Examples 1-9 to optionally include wherein the at least one enclosure shell includes a first enclosure shell and a second enclosure shell, the filler cavities of the first and second enclosure shells are filled with the heat transfer filler, and the heat transfer filler in the first and second enclosure shells is in communication through one or more filler communication ports.

Example 11 can include, or can optionally be combined with the subject matter of Examples 1-10 to optionally include wherein the first enclosure shell is on a first face of the substrate and the second enclosure shell is on a second face of the substrate, and the one or more filler communication ports extend through the substrate.

Example 12 can include, or can optionally be combined with the subject matter of Examples 1-11 to optionally include wherein the device housing consists of one of a mobile phone housing, tablet housing, smartphone housing, laptop housing, two in one device housing, desktop computer housing, or server node housing.

Example 13 can include, or can optionally be combined with the subject matter of Examples 1-12 to optionally include an electronic component assembly comprising: a substrate having a first face and an opposed second face; one or more electronic components coupled with either or both of the first and second faces; and a filler interface heat transfer system coupled with the substrate, the filler interface heat transfer system includes: at least one enclosure shell coupled with one of the first or second faces, the at least one enclosure shell surrounds a filler cavity including the one or more electronic components therein, and a heat transfer filler within the filler cavity, the heat transfer filler includes a contoured filler profile conforming to at least the one or more electronic components.

Example 14 can include, or can optionally be combined with the subject matter of Examples 1-13 to optionally include wherein the heat transfer filler surrounds the one or more electronic components and is distributed across the substrate within the enclosure shell.

Example 15 can include, or can optionally be combined with the subject matter of Examples 1-14 to optionally include wherein the contoured filler profile conforms to an enclosure profile of the at least one enclosure shell.

Example 16 can include, or can optionally be combined with the subject matter of Examples 1-15 to optionally include wherein the one or more electronic components include a component profile and the contoured filler profile is greater than the component profile.

Example 17 can include, or can optionally be combined with the subject matter of Examples 1-16 to optionally include wherein a composite profile includes the component profile and a substrate profile, and the composite profile matches the contoured filler profile.

Example 18 can include, or can optionally be combined with the subject matter of Examples 1-17 to optionally include wherein the heat transfer filler consists of at least one of a phase change material or a heat transfer fluid.

Example 19 can include, or can optionally be combined with the subject matter of Examples 1-18 to optionally include wherein the at least one enclosure shell seals the heat transfer filler within the filler cavity and retains the contoured filler profile in conformation to at least the one or more electronic components.

Example 20 can include, or can optionally be combined with the subject matter of Examples 1-19 to optionally include wherein the at least one enclosure shell includes a first enclosure shell and a second enclosure shell, the filler cavities of the first and second enclosure shells are filled with the heat transfer filler, and the heat transfer filler in the first and second enclosure shells is in communication through one or more filler communication ports.

Example 21 can include, or can optionally be combined with the subject matter of Examples 1-20 to optionally include wherein the first enclosure shell is on the first face of the substrate and the second enclosure shell is on the opposed second face of the substrate, and the one or more filler communication ports extend through the substrate.

Example 22 can include, or can optionally be combined with the subject matter of Examples 1-21 to optionally include wherein the filler interface heat transfer system includes a distributive heat path including at least the heat transfer filler and the at least one enclosure shell, and the distributive heat path is configured to distribute heat from the one or more electronic components into the heat transfer filler and the at least one enclosure shell.

Example 23 can include, or can optionally be combined with the subject matter of Examples 1-22 to optionally include a method for making an electronic device comprising: coupling an enclosure shell with a substrate, the enclosure shell includes a filler cavity having one or more electronic components coupled with the substrate therein; and interfacing a heat transfer filler with the one or more electronic components in the filler cavity, interfacing includes: delivering the heat transfer filler to the filler cavity through a filler inflow port extending into the filler cavity, conforming the heat transfer filler to at least a component profile of the one or more electronic components, and sealing the enclosure shell filled with the heat transfer filler.

Example 24 can include, or can optionally be combined with the subject matter of Examples 1-23 to optionally include wherein coupling the enclosure shell with the substrate includes adhering the enclosure shell with the substrate.

Example 25 can include, or can optionally be combined with the subject matter of Examples 1-24 to optionally include wherein coupling the enclosure shell with the substrate includes soldering the enclosure shell to the substrate.

Example 26 can include, or can optionally be combined with the subject matter of Examples 1-25 to optionally include wherein the enclosure shell includes first and second enclosure shells, and delivering the heat transfer filler to the filler cavity includes: delivering the heat transfer filler to the filler cavity of the first enclosure shell through the filler inflow port, and delivering the heat transfer filler to the filler cavity of the second enclosure shell through a filler communication port extending between the first and second enclosure shells.

Example 27 can include, or can optionally be combined with the subject matter of Examples 1-26 to optionally include wherein conforming the heat transfer filler to at least the component profile includes fluidly surrounding each of the one or more electronic components.

Example 28 can include, or can optionally be combined with the subject matter of Examples 1-27 to optionally include wherein interfacing the heat transfer filler with the one or more electronic components in the filler cavity includes conforming the heat transfer filler to the enclosure profile of the enclosure shell.

Example 29 can include, or can optionally be combined with the subject matter of Examples 1-28 to optionally include coupling the enclosure shell with a device housing, the device housing including the substrate and the one or more electronic components therein.

Example 30 can include, or can optionally be combined with the subject matter of Examples 1-29 to optionally include wherein coupling the enclosure shell with the device housing includes engaging at least a portion of the enclosure shell in surface to surface contact with the device housing.

Example 31 can include, or can optionally be combined with the subject matter of Examples 1-30 to optionally include wherein coupling the enclosure shell with the device housing includes coupling the enclosure shell with the device housing with one or more heat pipes.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments in which the disclosure can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the disclosure should be determined with reference to the appended claims, along with the full scope of equivalents to which such claims are entitled.

What is claimed is:

1. An electronic device comprising:
a device housing;
a substrate within the device housing and coupled with the device housing;
one or more electronic components coupled with the substrate, the one or more electronic components and the substrate include a composite profile; and
a filler interface heat transfer system coupled with the one or more electronic components, the filler interface heat transfer system includes:
at least one enclosure shell coupled with the substrate, the at least one enclosure shell surrounds a filler cavity, the one or more electronic components and the composite profile,
a heat transfer filler within the filler cavity, the heat transfer filler includes a contoured filler profile conformed along and engaged along the composite profile, and
a distributive heat path including the heat transfer filler and the at least one enclosure shell, the distributive heat path is configured to distribute heat from the one or more electronic components into the heat transfer filler and the at least one enclosure shell and transfer heat from the heat transfer filler and the at least one enclosure shell to the device housing.

2. The device of claim 1, wherein the heat transfer filler consists of one of a phase change material or a heat transfer fluid.

3. The device of claim 1, wherein the at least one enclosure shell is coupled with the device housing.

4. The device of claim 3, wherein the at least one enclosure shell is coupled in surface to surface contact with the device housing.

5. The device of claim 3, wherein the at least one enclosure shell is coupled with the device housing with one or more heat pipes.

6. The device of claim 1, wherein the at least one enclosure shell seals the heat transfer filler within the filler cavity and isolates the remainder of the device housing from the heat transfer filler.

7. The device of claim 1, wherein the one or more electronic components include a component profile and the contoured filler profile is greater than the component profile.

8. The device of claim 1, wherein contoured filler profile is conformed along and engaged along an enclosure profile of the at least one enclosure shell.

9. The device of claim 1, wherein the at least one enclosure shell includes a protective frame surrounding at least the one or more electronic components.

10. The device of claim 1, wherein the at least one enclosure shell includes a first enclosure shell and a second enclosure shell, the filler cavities of the first and second enclosure shells are filled with the heat transfer filler, and
the heat transfer filler in the first and second enclosure shells is in communication through one or more filler communication ports.

11. The device of claim 1, wherein the device housing consists of one of a mobile phone housing, tablet housing, smartphone housing, laptop housing, two in one device housing, desktop computer housing, or server node housing.

12. An electronic component assembly comprising:
a substrate having a first face and an opposed second face;
one or more electronic components coupled with either or both of the first and second faces; and
a filler interface heat transfer system coupled with the substrate, the filler interface heat transfer system includes:
at least one enclosure shell coupled with one of the first or second faces, the at least one enclosure shell surrounds a filler cavity including the one or more electronic components therein, and
a heat transfer filler within the filler cavity, the heat transfer filler includes a contoured filler profile conforming to at least the one or more electronic components.

13. The assembly of claim 12, wherein the heat transfer filler surrounds the one or more electronic components and is distributed across the substrate within the enclosure shell.

14. The assembly of claim 12, wherein the contoured filler profile conforms to an enclosure profile of the at least one enclosure shell.

15. The assembly of claim 12, wherein the one or more electronic components include a component profile and the contoured filler profile is greater than the component profile.

16. The assembly of claim 12, wherein the heat transfer filler consists of at least one of a phase change material or a heat transfer fluid.

17. The assembly of claim 12, wherein the at least one enclosure shell seals the heat transfer filler within the filler cavity and retains the contoured filler profile in conformation to at least the one or more electronic components.

18. The assembly of claim 12, wherein the at least one enclosure shell includes a first enclosure shell and a second enclosure shell, the filler cavities of the first and second enclosure shells are filled with the heat transfer filler, and
the heat transfer filler in the first and second enclosure shells is in communication through one or more filler communication ports.

19. The assembly of claim 18, wherein the first enclosure shell is on the first face of the substrate and the second enclosure shell is on the opposed second face of the substrate, and
the one or more filler communication ports extend through the substrate.

20. A method for making an electronic device comprising:
coupling an enclosure shell with a substrate, the enclosure shell includes a filler cavity having one or more electronic components coupled with the substrate therein; and
interfacing a heat transfer filler with the one or more electronic components in the filler cavity, interfacing includes:
delivering the heat transfer filler to the filler cavity through a filler inflow port extending into the filler cavity,
conforming the heat transfer filler to at least a component profile of the one or more electronic components, and
sealing the enclosure shell filled with the heat transfer filler.

21. The method of claim 20, wherein coupling the enclosure shell with the substrate includes soldering the enclosure shell to the substrate.

22. The method of claim 20, wherein the enclosure shell includes first and second enclosure shells, and delivering the heat transfer filler to the filler cavity includes:
delivering the heat transfer filler to the filler cavity of the first enclosure shell through the filler inflow port,
and delivering the heat transfer filler to the filler cavity of the second enclosure shell through a filler communication port extending between the first and second enclosure shells.

23. The method of claim 20, wherein conforming the heat transfer filler to at least the component profile includes fluidly surrounding each of the one or more electronic components.

24. The method of claim 20, wherein interfacing the heat transfer filler with the one or more electronic components in the filler cavity includes conforming the heat transfer filler to the enclosure profile of the enclosure shell.

25. The method of claim 20 comprising coupling the enclosure shell with a device housing, the device housing including the substrate and the one or more electronic components therein.
